(19) United States
(12) Patent Application Publication
(10) Pub. No.: US 2018/0338396 A1
(43) Pub. Date: Nov. 22, 2018

(54) ELECTRONIC COMPONENT HAVING ELECTROMAGNETIC SHIELDING AND METHOD FOR PRODUCING THE SAME

(71) Applicant: Murata Manufacturing Co., Ltd., Nagaokakyo-shi (JP)

(72) Inventors: Takeshi Torita, Philadelphia, PA (US); Yoshito Soda, Philadelphia, PA (US)

(21) Appl. No.: 15/596,445

(22) Filed: May 16, 2017

(51) Int. Cl. H05K 9/00

(52) U.S. Cl. CPC H05K 9/0088; H05K 1/181

(57) ABSTRACT

An electronic component having electromagnetic shielding, the electronic component having a body part of the electronic component and a coating layer that coats a surface of the body part and functions as the electromagnetic shielding. The coating layer has a layered material with a plurality of layers, each layer having a crystal lattice which is represented by: Mₙ₊₁Xₙ (wherein M is at least one metal of Group 3, 4, 5, 6, or 7; X is a carbon atom, a nitrogen atom, or a combination thereof; and n is 1, 2, or 3), and in which each X is positioned within an octahedral array of M, and having at least one modifier or terminal T selected from a hydroxy group, a fluorine atom, an oxygen atom, and a hydrogen atom on at least one of two opposing surfaces of each layer.

### TECHNICAL FIELD

The present invention relates to an electronic component having electromagnetic shielding and a method for producing the same.

### BACKGROUND ART

Conventionally, electromagnetic shielding has been used to prevent an electromagnetic wave (electromagnetic noise) generated from an electronic device or the like, from being spatially transmitted and causing another electronic device or the like to malfunction. As materials for forming the electromagnetic shielding (hereinafter simply referred to as “electromagnetic shielding materials”), electrically conductive materials such as metal and carbon are used.

In the case of a portable-type electronic device, electromagnetic shielding for an electronic circuit board is disposed in the electronic device. As such electromagnetic shielding, an electromagnetic shielding film including a metal layer is known (Patent Literature 1). The electromagnetic shielding film is disposed so as to cover the whole area of an electronic circuit board on which a plurality of electronic components are mounted.

In recent years, due to high-density mounting on electronic circuit boards, a problem that an electromagnetic wave generated in an electronic circuit can cause an electronic component on the electronic circuit to malfunction has arisen. Such a phenomenon is also referred to as “autointoxication”, and, to prevent this, it is required that electronic shielding is provided for each electronic component. However, it is difficult to appropriately and sufficiently cover each electronic component having a small size with an electromagnetic shielding film.

To address this, for example, it has been proposed to form a metal layer by using, as an electromagnetic shielding material, a metal paste in which metal fine particles in the form of paste serving as filler is dispersed and ejecting the metal paste onto the surface of one electronic component by a dispenser (paragraph 0034 of Patent Literature 2). In addition, it is also proposed to form a metal plating film on the surface of one electronic component via electroless plating (Patent Literature 3).

### CITATION LIST

### Patent Literature

Patent Literature 1: WO 2013/077108 A1

Patent Literature 2: JP 2004-6973 A

Patent Literature 3: JP 2014-123619 A

Patent Literature 4: US 2016/0360616 A1

Patent Literature 5: WO 2016/049109 A2

### Non Patent Literature

Non-Patent Literature 1: Faisal Shahzad, et al., “Electromagnetic interference shielding with 2D transition metal carbides (MXenes)”, Science, 09 Sep 2016, Vol. 353, Issue 6304, pp. 1137-1140

### SUMMARY OF INVENTION

### Technical Problem

However, in the above-described method of forming a metal layer by ejecting a metal paste containing metal particles by a dispenser, typically, a large amount of the metal paste is supplied onto the electronic component and the electronic component is buried in the metal paste. Therefore, the method is not suitable for forming electromagnetic shielding on the surface of the electronic component as a relatively thin coating layer. In addition, since typically spherical metal fine particles are dispersed in the metal paste, gaps are likely to be present between metal fine particles and thus electromagnetic waves are likely to be transmitted therethrough. Therefore, a high shielding effect cannot be achieved.

In addition, in the above-described method of forming a metal plating film on an electronic component via electroless plating, the electronic component is immersed in a plating liquid (may be acidic or alkaline). Therefore, the plating liquid can infiltrate into the electronic component or enter the inside of the electronic component, and thus deterioration or malfunction of the electronic component can occur. To prevent this, application of sealing, a protective film, or the like is required, and thus a production process of the electronic component becomes complicated.

In the meantime, an electromagnetic shielding material containing graphene, which is one of two-dimensional material, is known as a novel electromagnetic shielding material (Patent Literature 4). For example, it is known that a coating layer formed by performing printing on a thin film or a flexible substrate with an electrically conductive ink in which plate-shaped nanographene is dispersed in a liquid medium can be used as electromagnetic shielding (Patent Literature 4). Such an electrically conductive graphene-containing ink does not have a sufficient electrical conductivity, and thus it can be considered that it is difficult to achieve a sufficient shielding effect even if the ink is applied on the surface of the electrical component. In addition, it is inevitable that hydrophobic groups and hydrophilic groups are both present on the surface of graphene due to a production method thereof. Therefore, it is difficult to select a solvent that has a high affinity for graphene, and graphene is not likely to wet and spread even if graphene is applied on the surface of the electronic component, and thus it can be considered that it is difficult to form a coating layer having a uniform thickness.

In recent years, MXene has caught much attention as a novel material that has a high electrical conductivity and a high thermal conductivity (Patent Literature 5). MXene is one of so-called two-dimensional material and is a layered material, as will be described, comprising a plurality of layers, each layer having a crystal lattice which is represented by M₊₁Xₙ (wherein M is at least one metal of Group 3, 4, 5, 6, or 7, X is a carbon atom and/or a nitrogen atom, and n is 1, 2, or 3), and in which each X is positioned within an octahedral array of M, and having a terminal (or modifier) T such as a hydroxy group, a fluorine atom, an oxygen atom, or a hydrogen atom on the surface of each layer. It has been reported that MXene has a high shielding effect (EMI SE) per unit thickness in the form of a film of a MXene alone or a film of a MXene-polymer composite (Non-Patent Literature 1). More specifically, in both of the case of a film of Ti₃C₂Tₓ alone, which is one of MXene, and the case of a film of a Ti₃C₂Tₓ-sodium alginate composite, a shielding effect of about 50 dB is achieved with a film thickness of about 10 μm (see FIG. 4A of Non-Patent Literature 1). However, in the case of such films, when providing each electronic component with electromagnetic shielding, it is required to wrap the electronic component in the film while folding the film, and thus the process is complicated. Therefore, it is difficult to use such films for electromagnetic shielding of electronic components.

In these circumstances, the present inventors have reached the present invention as a result of diligent studies to provide a novel electromagnetic component having electromagnetic shielding.

### Solution to Problem

According to an aspect of the present invention, there is provided an electronic component having electromagnetic shielding, the electronic component including:

(a) a body part of the electronic component; and

(b) a coating layer that coats a surface of the body part and functions as the electromagnetic shielding,

wherein the coating layer comprises a layered material comprising a plurality of layers, each layer

having a crystal lattice which is represented by a formula below:

Mₙ₊₁Xₙ

(wherein M is at least one metal of Group 3, 4, 5, 6, or 7;

X is a carbon atom, a nitrogen atom, or a combination thereof; and

n is 1, 2, or 3), and in which each X is positioned within an octahedral array of M, and

having at least one modifier or terminal T selected from the group consisting of a hydroxy group, a fluorine atom, an oxygen atom, and a hydrogen atom on at least one of two opposing surfaces of said each layer. To be noted the electromagnetic shielding is also referred to as electromagnetic interference (EMI) shielding.

In the electronic component of the present invention, since a coating layer containing the prescribed layered material (also referred to as “MXene” in this specification) is provided on the surface of the body part of the electronic component as electromagnetic shielding and MXene has a high electrical conductivity (particularly electromagnetic wave absorbing performance) and is hydrophilic, a coating layer having a uniform thickness can be formed to achieve a high shielding effect via a method that is simple and harmless to the electronic component as will be described later, and, as a result of this, a novel electronic component including such a coating layer as the electromagnetic shielding can be obtained.

In an embodiment of the present invention, the coating layer may further comprise a water-soluble and/or hydrophilic organic binder.

According to another aspect of the present invention, there is provided a method for producing an electronic component having electromagnetic shielding, which comprises:

(i) preparing a dispersion in which a layered material comprising a plurality of layers is dispersed in a liquid medium (or a fluid medium, the same applies hereafter), each layer

having a crystal lattice which is represented by a formula below:

Mₙ₊₁Xₙ

(wherein M is at least one metal of Group 3, 4, 5, 6, or 7;

X is a carbon atom, a nitrogen atom, or a combination thereof; and

n is 1, 2, or 3), and in which each X is positioned within an octahedral array of M, and

having at least one modifier or terminal T selected from the group consisting of a hydroxy group, a fluorine atom, an oxygen atom, and a hydrogen atom on at least one of two opposing surfaces of said each layer; and

(ii) forming a coating layer derived from the dispersion by applying the dispersion on a surface of a body part of the electronic component.

In an embodiment of the present invention, the liquid medium may comprise an aqueous solvent and a water-soluble organic binder.

In another embodiment of the present invention, the liquid medium may comprise a hydrophilic organic binder.

In an embodiment of the present invention, the surface of the body part of the electronic component may be hydrophilic.

In another embodiment of the present invention, the surface of the body part of the electronic component may have been subjected to hydrophilization treatment in advance. In such an embodiment, the hydrophilization treatment may be performed via at least one selected from the group consisting of plasma treatment, corona treatment, ultraviolet light irradiation, ultraviolet light-ozone treatment, and application of a hydrophilic coating agent.

In another embodiment of the present invention, the formation of the coating layer in the step (ii) may be performed by removing the liquid medium from the dispersion at least partially, or by curing the dispersion at least partially.

### Advantageous Effects of Invention

According to the present invention, since a coating layer containing MXene is provided on the surface of the body part of the electronic component as electromagnetic shielding and MXene has a high electrical conductivity (particularly electromagnetic-wave absorbing performance) and is hydrophilic, a coating layer of a uniform thickness can be formed to achieve a high shielding effect via a method that is simple and harmless to the electronic component, and, as a result of this, a novel electronic component including such a coating layer as the electromagnetic shielding can be obtained. In addition, according to the present invention, a method for producing the electronic component can be also provided.

### BRIEF DESCRIPTION OF DRAWINGS

FIG. 1 is a schematic section view of an electronic component having electromagnetic shielding according to an embodiment of the present invention.

FIG. 2 is an enlarged schematic sectional view of a part corresponding to a region X of the electronic component having electromagnetic shield of FIG. 1.

FIG. 3 is a schematic sectional view of MXene that is a layered material usable for electromagnetic shielding according to an embodiment of the present invention.

FIG. 4 is a photograph showing a result of a test in an example of the present invention.

FIG. 5 is a photograph showing a result of a test in a comparative example of the present invention.

### DESCRIPTION OF EMBODIMENTS

Although an electronic component having electromagnetic shielding according to the present invention and a method for producing the same will be described in detail through some embodiments, the present invention is not limited to these embodiments.

### Embodiment 1

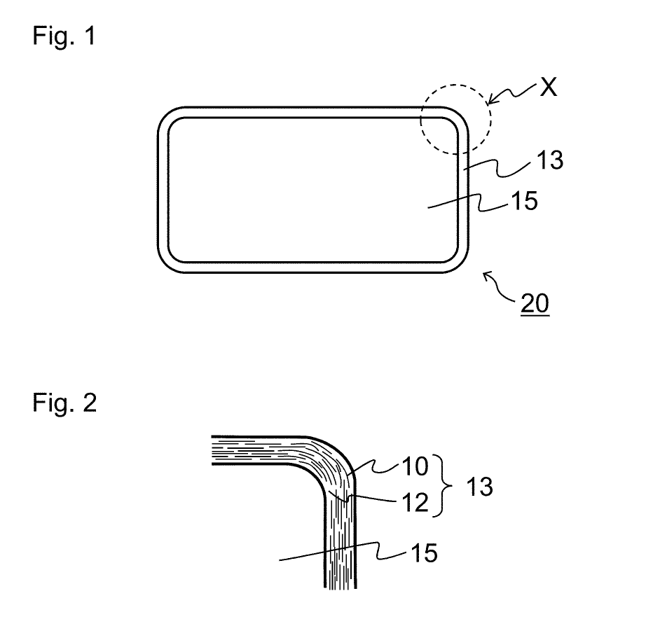

With reference to FIGS. 1 and 2, an electronic component 20 having electromagnetic shielding according to the present embodiment includes:

(a) a body part 15 of the electronic component, and

(b) a coating layer 13 that coats a surface of the body part 15 and functions as the electromagnetic shielding,

wherein the coating layer 13 contains a prescribed layered material including a plurality of layers.

A material usable as the prescribed layered material in the present embodiment is MXene, which is defined as follows:

A layered material including a plurality of layers, and each layer

having a crystal lattice which is represented by the following formula:

Mₙ₊₁Xₙ

(wherein M is at least one metal of Group 3, 4, 5, 6, or 7 and may include at least one metal selected from the group consisting of so-called early transition metals, for example, Sc, Ti, Zr, Hf, V, Nb, Ta, Cr, Mo, and Mn;

X is a carbon atom, a nitrogen atom, or a combination thereof; and

n is 1, 2, or 3), and in which each X is positioned in an octahedral array of M, and

having at least one modifier or terminal T selected from the group consisting of a hydroxy group, a fluorine atom, an oxygen atom, and a hydrogen atom, preferably a hydroxy group, on at least one of two opposing surfaces of said each layer.

Such MXene can be obtained by selectively etching A atoms from an MAX phase. The MAX phase has a crystal lattice which is represented by the following formula:

Mₙ₊₁AXₙ

(wherein M, X, and n are the same as described above; and A is at least one element of Group 12, 13, 14, 15, or 16, normally an element of A Group, typically of IIIA Group or IVA Group, more specifically at least one element selected from the group consisting of Al, Ga, In, Tl, Si, Ge, Sn, Pb, P, As, S, and Cd, and is preferably Al), and in which each X is positioned in an octahedral array of M, and has a crystal structure in which a layer constituted by A atoms is positioned between layers represented by Mₙ₊₂Xₙ. The MAX phase schematically includes a repeating unit in which each one of layers of X atoms is disposed between adjacent layers of n+1 layers of M atoms (these are also collectively referred to as a “Mₙ₊₁Xₙ layer”), and a layer of A atoms (“A atom layer”) is disposed as a layer next to the (n+1)th layer of M atoms. The A atom layer is removed by selectively etching A atoms from the MAX phase. This causes delamination of the Mₙ₊₁Xₙ layer, the exposed surface of the Mₙ₋Xₙ layer is modified by hydroxy groups, fluorine atoms, oxygen atoms, hydrogen atoms, or the like present in an etching liquid (an aqueous solution of fluorine-containing acid is typically used, but not limited to this), and thus the surface is terminated.

For example, the MAX phase is Ti₃AlC₂, and MXene is Ti₃C₂Tₛ.

In the present invention, MXene may contain remaining A atoms at a relatively small amount, for example, equal to or less than 10% by mass with respect to the original content of A atoms.

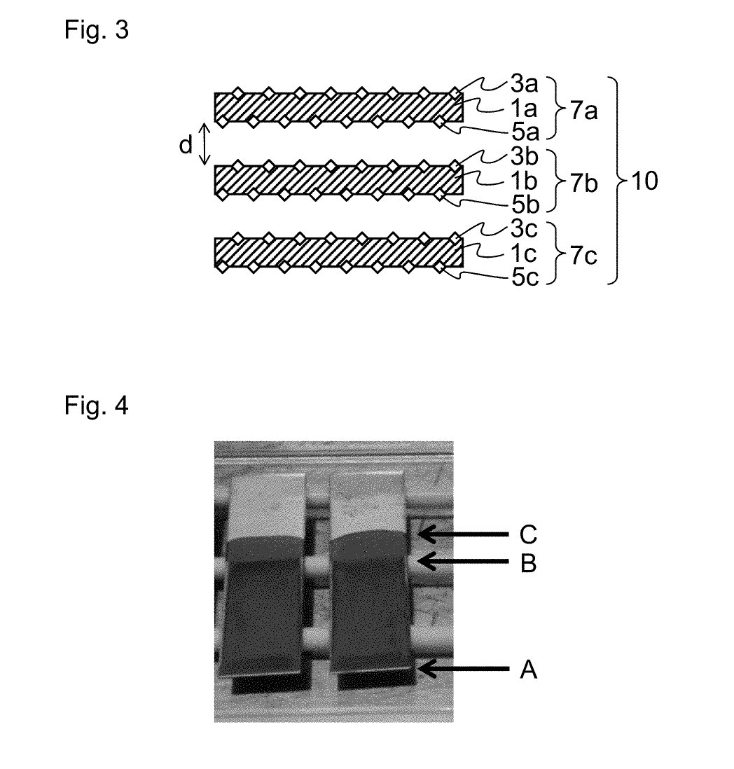

As schematically illustrated in FIG. 3, MXene 10 obtained in this way may be a layered material including two or more (although three layers are illustrated in the figure as an example, this is not limiting) MXene layers (these are also represented by “Mₙ₊XₙTₛ”, and s is an arbitrary number) 7a, 7b, and 7c obtained by modifying or terminating the surfaces of Mₙ₊₁Xₙ layers 1a, 1b, and 1c with modifiers or terminals T 3a, 5a, 3b, 5b, 3c, and 5c. The MXene 10 may be a plurality of MXene layers which are separated and individually present (single-layer structure), a laminate in which a plurality of MXene layers are laminated with gaps interposed therebetween (multi-layer structure), or a mixture thereof. MXene may be an aggregation (may be also referred to as particles, powder, or flakes) of individual MXene layers (single layers) and/or laminates of MXene layers. In the case of the laminate, two adjacent MXene layers (for example, 7a and 7b, and 7b and 7c) do not need to be completely separated, and may be partially in contact with each other.

Although the following description is not given to limit the present embodiment, each layer of MXene (corresponding to MXene layers 7a, 7b, and 7c described above) has a thickness of, for example, not less than 0.8 nm and not more than 5 nm, and particularly not less than 0.8 nm and not more than 3 nm (the thickness may vary depending mainly on the number of M atom layers included in each layer), and the maximum dimension of MXene in a plane parallel to the layer (two-dimensional sheet plane) is, for example, not less than 0.1 μm and not more than 200 μm, particularly not less than 0.5 μm and not more than 100 μm, and yet particularly not less than 1 μm and not more than 40 μm. In the case where MXene is a laminate, as to each individual laminate, the inter-layer distance (or a gap dimension indicated by d in FIG. 3) is, for example, not less than 0.8 nm and not more than 10 nm and particularly not less than 0.8 nm and not more than 5 nm, and yet particularly about 1 nm, and the total number of layers may be 2 or more, and, for example, is not less than 50 and not more than 100,000 and particularly not less than 1,000 and not more than 20,000, the thickness in the lamination direction is, for example, not less than 0.1 μm and not more than 200 μm and particularly not less than 1 μm and not more than 40 μm, and the maximum dimension in a plane (two-dimensional sheet plane) perpendicular to the lamination direction is, for example, not less than 0.1 μm and not more than 100 μm and particularly not less than 1 μm and not more than 20 μm. To be noted, these dimensions are obtained as number average dimensions (for example, number average of at least 40 samples) based on a scanning electron microscope (SEM) image or a transmission electron microscope (TEM) image.

MXene has a remarkably high carrier density (carrier concentration) and a high electrical conductivity in an in-plane direction, and also has a high electrical conductivity (for example, compared with graphene) in the thickness direction because MXene contains metal atoms M. With a high electrical conductivity in the thickness direction, conduction between MXene (single layers and/or laminates) is more likely to be achieved, and thus a high shielding effect can be achieved (for example, in either case of MXene alone or a state in which MXene is dispersed in a forming material). In particular, MXene is a layered material and has a high electromagnetic wave absorbing performance due to internal multiple reflection of electromagnetic waves. Further, since MXene contains metal atoms M, MXene also has a high thermal conductivity (for example, compared with graphene).

In addition, MXene includes surface modifiers or terminals T that may be polar or ionic, and thus the surface thereof is highly hydrophilic. The contact angle of water on the surface of MXene may be, for example, 45° or less, and typically not less than 20° and not more than 35°. In MXene, the modifiers or terminals T may be present periodically or regularly in accordance with the crystal structure of Mₙ₊₁Xₙ (it is to be noted that no polar or ionic modifiers, terminals, or the like that are regularly arranged are present on graphene).

Any material may be used for the coating layer 13 as long as the coating layer 13 includes the MXene 10 that is a layered material. The content of MXene in the coating layer 13 may be, for example, not less than about 50% by mass and not more than 100% by mass.

In addition, the coating layer 13 may further contain other components. For example, the coating layer 13 may further contain carbon nanotube. Carbon nanotube is a material formed in a tube shape from a single layer or multiple layers of graphene sheets, and has a diameter (outer diameter) in the order of nanometers or less. By adding carbon nanotube, the electrical conductivity of the coating layer 13 can be improved, and thus a shielding property thereof can be improved. The carbon nanotube may be carried on the surface of plural layers of MXene and/or in the interface of two adjacent layers of MXene. Although the dimension of the carbon nanotube may be selected as appropriate, the average diameter thereof may be, for example, not less than 0.5 nm and not more than 200 nm and particularly not less than 1 nm and not more than 50 nm, and the average length thereof may be, for example, not less than 0.5 μm and not more than 200 μm and particularly not less than 1 μm and not more than 50 μm. To be noted, these dimensions are obtained as number average dimensions (for example, number average of at least 40 samples) based on a scanning electron microscope (SEM) image or a transmission electron microscope (TEM) image.

The ratio of carried carbon nanotube is not particularly limited, but may be, for example, not less than 1 part by mass and not more than 50 parts by mass and particularly not less than 1 part by mass and not more than 10 parts by mass with respect to 100 parts by mass of MXene.

In addition, for example, the coating layer 13 may contain an arbitrary appropriate forming material 12, for example, a binder, and may contain an additive (for example, a viscosity modifier, a curing agent, or the like) in some case. With reference to FIG. 2 (a partially enlarged view of a region X of the electronic component illustrated in FIG. 1), the MXene 10 may be dispersed in the forming material 12, be embedded in the forming material 12, and be either a state of being completely coated or a state of being partially exposed.

The binder may be a water-soluble and/or hydrophilic organic binder. The water-soluble and/or hydrophilic organic binder has a good wettability with respect to MXene having a hydrophilic surface, and thus MXene can be easily dispersed in the organic binder and the organic binder can be easily impregnated into interfaces of MXene layers. Therefore, the organic binder may be suitably used. In the case of a laminate of MXene, the inter-layer distance of layers of MXene can be increased by the organic binder impregnating into interfaces of MXene layers, but this is not limiting.

There are various water-soluble and/or hydrophilic organic binders, and selection may be made as appropriate from among a wide variety. Examples of water-soluble organic binders include polyvinyl alcohol. Examples of hydrophilic organic binders include polymers such as polypyrrole, (meth)acrylic resin, and cellulose, thermosetting resins such as polyvinyl butyral and polyester, and curable resins such as phenol-curable epoxy resin and polyurethane. These polymers (or polymeric materials) and/or resins may contain other monomer units and arbitrary appropriate substituents and/or modifying groups.

Alternatively, the coating layer 13 may be substantially constituted by the MXene 10, and gaps between layers and/or laminates of the MXene 10 may be spaces.

The coating layer 13 described above may coat the surface of the body part 15 of the electronic component 20 at least partially. Although the body part 15 of the electronic component 20 is illustrated in FIG. 1 in a simplified manner, the electronic component 20 may be provided with an arbitrary appropriate number of electrodes (not illustrated), and the electrodes may be constituted by, for example, nickel, copper, silver, and/or gold. Although the following does not restrict the present embodiment, it is preferable that the coating layer 13 coats as large part as possible, preferably substantially the whole area, of the surface of the body part 15 of the electronic component (however, although the coating layer 13 can be disposed so as not to be directly in contact with an electrode for operating the electronic component 20, the coating layer 13 may be directly in contact with and electrically connected to a ground electrode).

The thickness of the coating layer 13 may be appropriately selected in accordance with a material used for the coating layer and a desired shielding property, and may be, for example, not less than 0.1 μm and not more than 200 μm and preferably not less than 1 μm and not more than 40 μm.

The electronic component 20 is not particularly limited, may be, for example, any of a chip component, other surface-mounted components (for example, QFP, SOP, BGA, and the like), and a lead component, and may be representatively a chip component. These may be individual electronic components or constituents of an electronic circuit board mounted on a board. The surface of the body part 15 of the electronic component 20 may be formed from an arbitrary appropriate material, for example, ceramics, glass, plastics, resin (for example, epoxy resin or ABS resin), or metal, and these may be constituting members that determine an electrical property of the electronic component, or may be protective layers, housings, or electrodes.

The electronic component 20 of the present embodiment includes the coating layer 13 containing MXene, which has a high electrical conductivity, and the coating layer 13 functions as electromagnetic shielding. In the case where the electronic component 20 of the present embodiment is exposed to an electromagnetic wave, the electromagnetic wave can be absorbed and/or reflected by MXene, and, preferably, a high shielding effect can be achieved due to multiple reflection that is characteristic of MXene. In addition, MXene is a layered material, and is likely to exist substantially parallel to an interface between the coating layer 13 and the body part 15 (see FIG. 2) in the coating layer 13, and electromagnetic waves is not likely to be transmitted through a gap of MXene. Therefore, a high shielding effect can be achieved.

In the electronic component 20 of the present embodiment, the coating layer 13 includes the MXene 10 having a hydrophilic surface as described above, and is overall configured to show hydrophilicity. The surface of the body part 15 of the electronic component 20 to be coated by the coating layer 13 may be hydrophilic, or, alternatively in some case, may be hydrophilized in advance via a method that is simple and harmless to the electronic component. As described above, the MXene 10, the coating layer 13 that contains the MXene 10, and the surface of the body part 15 of the electronic component 20 can be made to be hydrophilic, and the material of the coating layer 13 sufficiently wets, spreads on, and harmonizes with the surface of the body part 15. Therefore, the coating layer 13 can be formed in a uniform thickness.

### Embodiment 2

The present embodiment is related to a method for producing an electronic component having electromagnetic shielding according to Embodiment 1. Those that have been described in Embodiment 1 also apply to the present embodiment unless any particular description is given.

First, a dispersion in which at least MXene is dispersed in a liquid medium is prepared. MXene similar to that has been described in Embodiment 1 may be used. A dispersion in which MXene and carbon nanotube are dispersed in a liquid medium may be prepared. The dispersion may be in the form of a coating liquid (may be also referred to as “ink”) or in the form of a paste.

The liquid medium may be a water-soluble and/or hydrophilic binder, an aqueous solvent, a hydrophilic organic solvent, or a mixture of two or more of these, and may contain an additive or the like as appropriate.

For example, the liquid medium may contain an aqueous solvent and a water-soluble organic binder (such a liquid medium will be hereinafter also referred to as an “aqueous liquid medium”). The materials described in Embodiment 1 may be used for the water-soluble organic binder, and the water-soluble organic binder may be present in the liquid medium in a state of being dissolved in an aqueous medium. The aqueous solvent is representatively water, but is not limited to this, and may be an arbitrary appropriate water-based composition.

Meanwhile, for example, the liquid medium may contain a hydrophilic organic binder (such a liquid medium will be hereinafter also referred to as a “hydrophilic liquid medium”). The materials described in Embodiment 1 may be used for the hydrophilic organic binder, and the hydrophilic organic binder may be present in the liquid medium alone or in a state of being dissolved in a hydrophilic organic solvent. Examples of the hydrophilic organic solvent include alcohols (representatively ethanol and methanol).

Since the liquid medium described above is aqueous or hydrophilic, the liquid medium has a good wettability on MXene having a hydrophilic surface, and thus MXene can be easily dispersed in the liquid medium (even without any dispersing agent), and the liquid medium can be easily impregnated into interfaces of MXene layers.

Then, the dispersion containing MXene in the liquid medium obtained via the operation described above is applied on the surface of the body part of the electronic component.

The surface of the electronic component and of the body part thereof may be similar to that have been described in Embodiment 1. In the case where the surface of the body part of the electronic component is hydrophilic, the dispersion may be directly applied on the surface of the substrate. In the case where the surface of the body part of the electronic component is not hydrophilic or the hydrophilicity of the surface of the body part is not sufficiently high, the surface is modified in advance by performing hydrophilization treatment on the surface, and the dispersion may be applied on the hydrophilized surface. The hydrophilization treatment may be performed via at least one method selected from, for example, the group consisting of plasma treatment, corona treatment, ultraviolet light irradiation, ultraviolet light-ozone treatment, and application of a hydrophilic coating agent. The hydrophilization treatments described above all have advantages of being simple and harmless to the electronic component. The plasma treatment, corona treatment, ultraviolet light irradiation, and ultraviolet light-ozone treatment are dry processes, and have an advantage of not requiring to be performed in vacuum. The condition of these treatments may be appropriately selected in accordance with the surface of the body part that is used. The application of the hydrophilic coating agent may be performed by just causing the coating agent to attach to a coating target surface of the body part of the electronic component, and can be performed under normal pressure and not exposed in a relatively high temperature depending on the hydrophilic coating agent that is used. As the hydrophilic coating agent, an arbitrary appropriate hydrophilic coating agent may be used. For example, LAMBIC series (manufactured by Osaka Organic Chemical Industry Ltd.) may be used.

The contact angle of water on the surface of the body part of the electronic component immediately before the dispersion is applied may be, for example, 45° or less and representatively not less than 20° and not more than 35°.

The method of application of the dispersion on the surface of the body part of the electronic component is not particularly limited, and may be performed, for example, via coating, immersion, and spraying. These methods of application are remarkably simple.

According to the present embodiment, since MXene having a hydrophilic surface, an aqueous or hydrophilic liquid medium, and a hydrophilic surface of a body part of an electronic component are used in combination as described above, a dispersion containing MXene and the liquid medium sufficiently wets and spreads on the surface of the body part of the electronic component, and thus a uniform precursor film can be formed. At this time, MXene in the dispersion (precursor film) applied on the surface of the electronic component is, under the normal gravity, likely to be oriented such that a two-dimensional sheet surface of MXene is substantially parallel to an in-plane direction of a coated surface of the body part of the electronic component (see FIG. 2). To be noted, the sectional views of the electronic component of FIGS. 1 and 2 are all similar when viewed from the side, from above, and from below. Although the present invention is not bound by any theory, it can be understood that the interaction between the coated surface and the two-dimensional sheet surface of MXene is larger than the influence of gravity.

Then, a coating layer derived from the dispersion is formed from the dispersion (precursor film) applied on the surface of the body part. Such a coating layer may have a uniform thickness.

The formation of the coating layer may be performed by, for example, removing the liquid medium from the dispersion at least partially (for example, removing the solvent by drying), or curing the dispersion at least partially (for example, curing the organic binder).

In this way, the electronic component 20 including the coating layer 13 as electromagnetic shielding as illustrated in FIG. 1 is produced. According to the present embodiment, a coating layer having a uniform thickness can be formed and a high shielding effect can be achieved via a method that is remarkably simple and harmless to the electronic component.

However, the electronic component having electromagnetic shielding described in Embodiment 1 is not limited to be produced by the production method described in Embodiment 2, and the electronic component may be produced via any other appropriate method.

### EXAMPLES

### (Test)

A model experiment was performed by the following procedure.

First, a copper plate having a longitudinal length of 40 mm, a lateral width of 10 mm, and a thickness of 0.5 mm whose portion from one end thereof (corresponding to a position A in FIG. 4 and hereinafter referred to as a “bottom portion”) to a height of 20 mm in the longitudinal direction (corresponding to a position B in FIG. 4) was plated with nickel was prepared as a specimen. This specimen is an illustrative model of a material whose surface is not hydrophilic. Meanwhile, as a coating liquid for forming a coating layer, a dispersion liquid (MXene content: about 1% by mass) in which powder of Ti₃C₂Tₛ (black powder of MXene of single layer and/or several layers, of which thickness in the lamination direction (average value of thicknesses including a thickness of a single layer) was about 200 nm in number average dimension based on a TEM image, and of which aspect ratio was not less than about 50 and not more than 100), which is a kind of MXene, is dispersed in water was prepared. The obtained coating liquid was uniformly black, and MXene was uniformly dispersed therein. It was recognized that MXene is easily wettable against water.

The specimen prepared as described above was hydrophilized by irradiating the whole area of the front surface and back surface of the specimen with ultraviolet light (irradiation condition is understood as 5.5 mW/cm²) by using a UV irradiation apparatus (model: H0011, wavelength: 308 nm, manufactured by USHIO INC.). The part from the bottom portion (corresponding to the position A in FIG. 4) to the height of 20 mm (corresponding to the position C in FIG. 4) of the hydrophilized specimen obtained in this way was immersed in the coating liquid (MXene-water dispersion liquid) prepared as described above by descending the hydrophilized specimen in the vertical direction, and the specimen was pulled up after being held in this state (descending speed: 2 mm/sec, held: 30 sec, pulling-up speed: 2 mm/sec).

The operation described above was performed on two specimens. FIG. 4 illustrates a photograph of the two specimens after being pulled up. As can be seen from FIG. 4, the coating liquid was applied on and uniformly wet and spread on the whole immersed area of the surface of the hydrophilized specimen immersed in the coating liquid. Then, by removing water by drying, a coating layer could be formed from MXene in a uniform thickness.

Thus, it was confirmed that the MXene-water dispersion liquid used as the coating liquid shows a high wettability with respect to hydrophilized nickel and hydrophilized copper and that a coating layer formed from MXene can be formed in a uniform thickness.

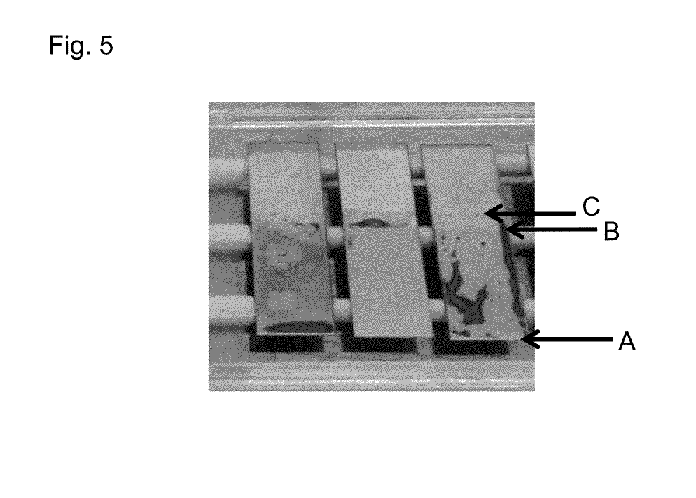

In addition, as a comparative example, a similar operation as described above was performed on three specimens except that the hydrophilization treatment was not performed. FIG. 5 illustrates a photograph of the three specimens after being pulled up. As can be seen from FIG. 5, the coating liquid did not wet or spread on the immersed area of the surface of the non-hydrophilized specimen immersed in the coating liquid.

The result described above has confirmed the difference of wettability of the MXene-water dispersion liquid according to whether or not hydrophilization treatment was performed by using a specimen having nickel and copper surfaces as an example of a material whose surface is not hydrophilic. Even in a case of other material, it can be considered that other materials similarly show a high wettability as long as the surface is hydrophilic (the surface may be originally hydrophilic or may have been hydrophilized), and thus it can be considered that a result similar to the above will be obtained.

In addition, the result described above is of the case where a dispersion liquid in which MXene is dispersed in water is used as the coating liquid. Even in a case where a dispersion liquid in which MXene is dispersed in a liquid medium that is a mixture of water and a water-soluble organic binder is used as the coating liquid, it can be considered that the wettability relationship between MXene, the liquid medium, and the coated surface is similar to the above, and thus it can be considered that a result similar to the above will be obtained.

### INDUSTRIAL APPLICABILITY

An electronic component having electromagnetic shielding according to the present invention can be used for applications of a wide range in which there is a risk that an electromagnetic wave (electromagnetic noise) is generated, is spatially transmitted, and causes another or the same electronic component or the like to malfunction.

### REFERENCE SIGNS LIST

1a, 1b, 1c Mₙ₊₁Xₙ layer

3a, 5a, 3b, 5b, 3c, 5c modifier or terminal T

7a, 7b, 7c MXene layer

10 MXene (layered material)

12 forming material (such as organic binder)

13 coating layer

15 body part

20 electronic component

1. An electronic component having electromagnetic shielding, the electronic component comprising:
(a) a body part of the electronic component; and
(b) a coating layer that coats a surface of the body part and functions as the electromagnetic shielding,
wherein the coating layer comprises a layered material comprising a plurality of layers, each layer having a crystal lattice which is represented by:
Mₙ₊₁Xₙ
wherein M is at least one metal of Group 3, 4, 5, 6, or 7;
X is a carbon atom, a nitrogen atom, or a combination thereof; and
n is 1, 2, or 3, and in which each X is positioned within an octahedral array of M, and having at least one modifier or terminal T selected from the group consisting of a hydroxy group, a fluorine atom, an oxygen atom, and a hydrogen atom on at least one of two opposing surfaces of said each layer.

2. The electronic component according to claim 1, wherein the coating layer further comprises a water-soluble and/or hydrophilic organic binder.

3. A method for producing an electronic component having electromagnetic shielding, which comprises:
(i) preparing a dispersion in which a layered material comprising a plurality of layers is dispersed in a liquid medium, each layer having a crystal lattice which is represented by:
Mₙ₊₁Xₙ
wherein M is at least one metal of Group 3, 4, 5, 6, or 7;
X is a carbon atom, a nitrogen atom, or a combination thereof; and
n is 1, 2, or 3, and in which each X is positioned within an octahedral array of M, and having at least one modifier or terminal T selected from the group consisting of a hydroxy group, a fluorine atom, an oxygen atom, and a hydrogen atom on at least one of two opposing surfaces of said each layer; and
(ii) forming a coating layer derived from the dispersion by applying the dispersion on a surface of a body part of the electronic component.

4. The method for producing an electronic component according to claim 3, wherein the liquid medium comprises an aqueous solvent and a water-soluble organic binder.

5. The method for producing an electronic component according to claim 3, wherein the liquid medium comprises a hydrophilic organic binder.

6. The method for producing an electronic component according to claim 3, wherein the surface of the body part of the electronic component is hydrophilic.

7. The method for producing an electronic component according to claim 3, wherein the surface of the body part of the electronic component has been subjected to hydrophilization treatment in advance.

8. The method for producing an electronic component according to claim 7, wherein the hydrophilization treatment is performed via at least one selected from the group consisting of plasma treatment, corona treatment, ultraviolet light irradiation, ultraviolet light-ozone treatment, and application of a hydrophilic coating agent.

9. The method for producing an electronic component according to claim 3, wherein the formation of the coating layer in the step (ii) is performed by removing the liquid medium from the dispersion at least partially, or by curing the dispersion at least partially.
